(19) United States
(12) Patent Application Publication
(10) Pub. No.: US 2024/0371421 A1
(43) Pub. Date: Nov. 7, 2024

(54) Systems and Methods for an Internal Clock Tree Structure in a Memory Device

(71) Applicant: Taiwan Semiconductor Manufacturing Company, Ltd., Hsinchu (TW)

(72) Inventors: Sanjeev Kumar Jain, Hsinchu (TW); Atul Katoch, Hsinchu (TW)

(21) Appl. No.: 18/488,506

(22) Filed: Oct. 17, 2023

Related U.S. Application Data
(60) Provisional application No. 63/499,720, filed on May 3, 2023.

(51) Int. Cl. G11C 7/22; G11C 8/18; G11C 11/413

(52) U.S. Cl. CPC G11C 7/222; G11C 8/18; G11C 11/413; H03K 19/20

(57) ABSTRACT

Systems and methods are provided a memory circuit that provides multiple clock signals to a local clock driver. One of the clock signals may be faster than the other and, as a result, at least one transistor of the local clock driver may be turned on early to improve the delay of the rising edge, the falling edge, or both edges of the slower clock signal. The local clock driver may include a first transistor electrically connected to the NAND gate and a second transistor electrically connected to the NOR gate. As a result of the additional, faster clock signal, a reduction of the clock to word line time in the memory circuit can be achieved.

### CROSS-REFERENCE TO RELATED APPLICATIONS

This application claims priority to U.S. Provisional Application No. 63/499,720, filed May 3, 2023, entitled “Internal Clock Tree Structure for High Speed Multi Bank SRAM,” which is incorporated herein by reference in its entirety.

### TECHNICAL FIELD

The technology described in this patent document relates generally to semiconductor memory systems, and more particularly to clock to word line paths in a semiconductor memory system.

### BACKGROUND

Memory devices are electronic data storage devices that include memory banks having memory locations for storage of data. Memory devices may be implemented by activating/transmitting commands (e.g., word line activation commands, column read commands, word line/bit line pre-charge commands, sense amplifier pre-charge commands, sense amplifier enable commands, read driver commands, write driver commands) to one or more memory arrays (e.g., a left array and a right array of a memory bank, four memory arrays of a memory bank). Each memory array contains a plurality of memory cells, typically arranged in rows and columns.

### BRIEF DESCRIPTION OF THE DRAWINGS

Aspects of the present disclosure are best understood from the following detailed description when read with the accompanying figures.

FIG. 1 is a diagram of an example clock tree architecture within a circuit for a semiconductor memory (e.g., SRAM), in accordance with various embodiments of the present disclosure.

FIG. 2 is a diagram of an example clock tree architecture within a circuit for a semiconductor memory (e.g., SRAM), in accordance with various embodiments of the present disclosure.

FIG. 3A is a diagram of a local clock driver architecture that may be incorporated into the circuit of FIG. 2, in accordance with various embodiments of the present disclosure.

FIG. 3B is a is a timing diagram showing an example operation of the local clock driver architecture of FIG. 3A, in accordance with various embodiments of the present disclosure.

FIG. 4A is a diagram of another local clock driver architecture that may be incorporated into the circuit of FIG. 2, in accordance with various embodiments of the present disclosure.

FIG. 4B is a is a timing diagram showing an example operation of the local clock driver architecture of FIG. 4A, in accordance with various embodiments of the present disclosure.

FIG. 5A is a diagram of an example address latch and pre-decoder that may be incorporated into the circuit of FIG. 2, in accordance with various embodiments of the present disclosure.

FIG. 5B is a diagram of an example circuit for a 3×8 pre-decoder, that may be incorporated into the circuit of FIG. 2, in accordance with various embodiments of the present disclosure.

FIG. 6 is a diagram of an example word line post-decoder that may be incorporated into the circuit of FIG. 2, in accordance with various embodiments of the present disclosure.

FIG. 7 is a flow diagram of an example method for providing clock signals to a memory bank of a memory circuit, in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Devices that include multiple memory banks may experience timing issues related to signals within those devices. Example memory banks may comprise a local input/output (LIO) circuit and one or more memory arrays. The memory bank may be coupled to a global input/output (GIO) circuit that generates a global input/output signal. In such memory devices, a clock may be used to keep operations in sequence. Some memory architectures use an external clock or a system-on-chip (SOC) clock to generate an internal clock for the memory. The internal clock is used to perform necessary functions of the memory device and signal processing operations, including read and write operations.

In memory devices, such as those described above, there is often a demand for a high speed register file (e.g., SRAM register file), and the access time associated therewith is typically the sum of three components: (i) clock to word line time, (ii) word line to sense amp time, and (iii) sense amp time to Q time. The present disclosure relates, in embodiments, to reducing the first item, the clock to word line time. Clock to word line delay can be measured as the sum of the clock to internal clock generation in global control (GCTRL), the clock propagation time from first bank to last bank local control (LCTRL), the clock pre decoder delay in LCTRL, and the post decoder delay in WL driver. Relatedly, since only one internal clock (ICLK) is typically available from global control to local control of the last bank, it may be difficult to drive internal clock to the last bank due to increased wire resistance, which can produce a longer delay due to increase RC of the internal clock and also create signal integrity problems.

Recognizing these issues, embodiments of the present disclosure provide circuits, methods, and devices that add a second, faster clock in order to improve the delay of the main internal clock. In other words, two internal clock signals (e.g., ICLK[0] and ICLK[1]) may be generated in global control. For example, ICLK[1] may be provided to some memory banks of a memory device, while ICLK[0] may be provided to all memory banks of the memory device. The ICLK[0] may function in a similar manner to ICLK of existing architectures in some ways. The second internal clock (ICLK[1]) may be a faster clock compared to ICLK[0], and may connect to a local clock driver in order to improve the rising and falling slope of ICLK[0], which may thereby improve clock delay in local control. By providing an additional clock signal that is faster than the original clock signal, the transistor of the local clock driver may be turned on early to improve the delay of the rising/falling edge of the first clock. As will be further described, the second clock signal may be transmitted to various components of each local clock driver, such as a NAND gate and/or a NOR gate of the local clock driver. Accordingly, through the introduction of this second clock signal, embodiments of the present disclosure can reduce the clock to word line time.

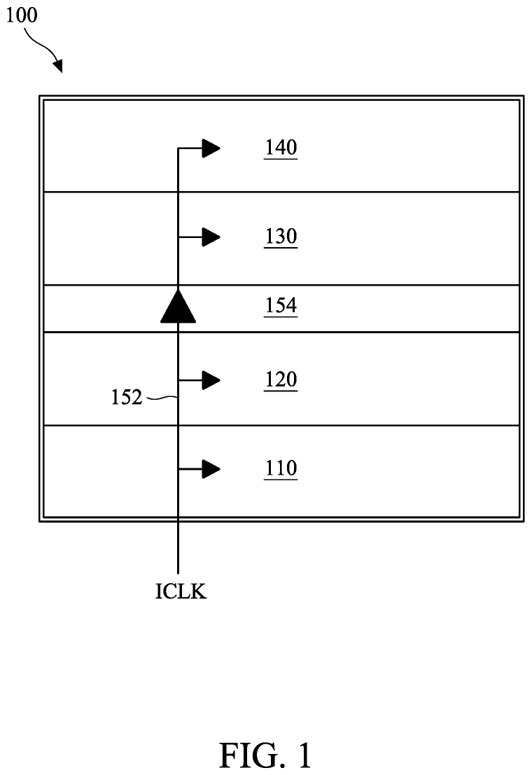

FIG. 1 is a diagram of an example clock tree architecture within a circuit 100 for a semiconductor memory (e.g., SRAM). As shown, the circuit 100 includes four memory banks: a first memory bank 110, a second memory bank 120, a third memory bank 130, and a fourth memory bank 140. Each of the memory banks 110, 120, 130, 140 may include a number of memory arrays that have a plurality of memory cells for storing information. In this example architecture, multiple internal clock signals (e.g., ICLK[0] and ICLK[1]) 152 may be provided to the memory banks 110, 120, 130, 140 in order to support necessary functions of the memory device and signal processing operations. For instance, the clock signals (ICLK[0] and ICLK[1]) may help facilitate the process of storing information to the memory banks 110, 120, 130, 140, which is known as “writing,” and/or the process of obtaining information stored in the memory banks 110, 120, 130, 140, which is known as “reading.” As depicted, a clock buffer 154 may be positioned between the second memory bank 120 and the third memory bank 130, and may function to receive and provide the clock signals (ICLK[0] and ICLK[1]) to the third memory bank 130 and the fourth memory bank 140. The clock buffer may alter the clock signals (ICLK[0] and ICLK[1]) prior to providing it the third memory bank 130 and the fourth memory bank 140, as necessary.

The internal clock signals 152 of the circuit 100 may be generated to follow a clock cycle within the memory device. At the start of a clock cycle, a global clock signal (CLK) (not depicted) may transition from logic low (“0”) to logic high (“1”). The global clock signal (CLK) may alternate between logic low (“0”) and logic high (“1”), for example, based on oscillations of an oscillator (e.g., a quartz crystal) within the memory device. Based on the transition of the global clock signal (CLK) from logic low (“0”) to logic high (“1”), the internal clock signals (ICLK[0] and ICLK[1]) 152 may also transition from logic low (“0”) to logic high (“1”). The internal clock signals (ICLK[0] and ICLK[1]) 152 may be generated by a clock generator in the control block of the memory device 100. Based on the rising edge (e.g., the transition from logic low to logic high) and the falling edge (e.g., the transition from logic high to logic low) of at least one of the internal clock signals (ICLK[0] and ICLK[1]), numerous operations within the memory device (e.g., writing information to a memory bank) may be timely performed.

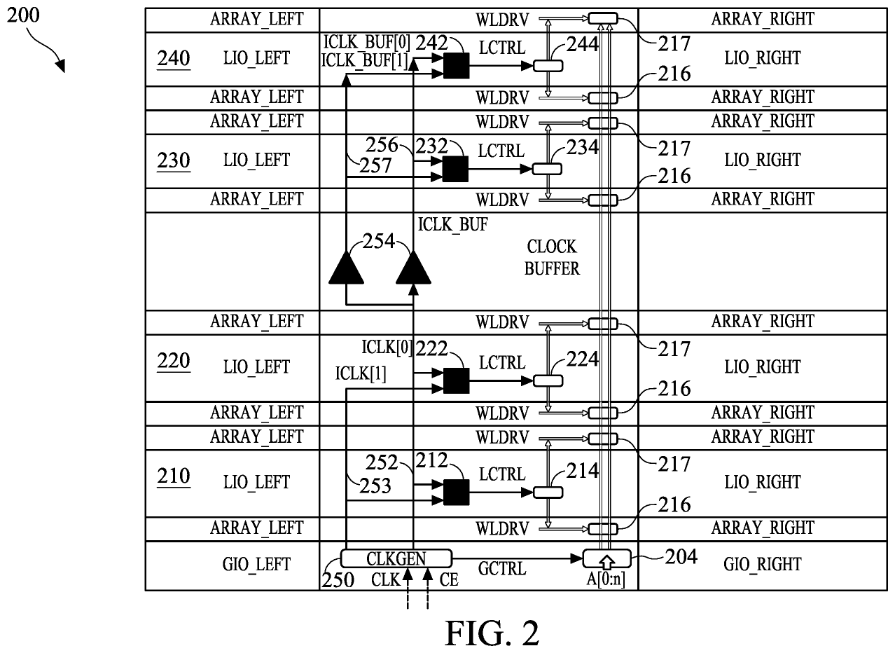

FIG. 2 is a diagram of an example clock tree architecture within a circuit 200 for a semiconductor memory (e.g., SRAM), in accordance with various embodiments of the present disclosure. Similar to FIG. 1, the circuit 200 includes four memory banks 210, 220, 230, 240, which each include multiple memory arrays (e.g., “ARRAY LEFT” and “ARRAY RIGHT”). Unlike in FIG. 1, additional components of each memory bank have been depicted in FIG. 2. For instance, within the clock tree architecture, each memory bank 210, 220, 230, 240 includes a local clock driver 212, 222, 232, 242 configured to receive clock signals and to improve the rising and falling slope of the received clock signals, a clock pre-decoder 212, 222, 232, 242 configured to receive the improved clock signals and to provide local control operations (e.g., to generate word line clock signals) in tandem with a plurality of word line post decoders 216, 217, 226, 227, 236, 237, 236, 237, which may be in communication with a global address latch and pre-decoder 204. As described above, if the clock tree architecture of FIG. 2 instead relied on a single internal clock signal being provided to each local clock driver, it may be difficult to drive the internal clock to the last bank due to increased wire resistance.

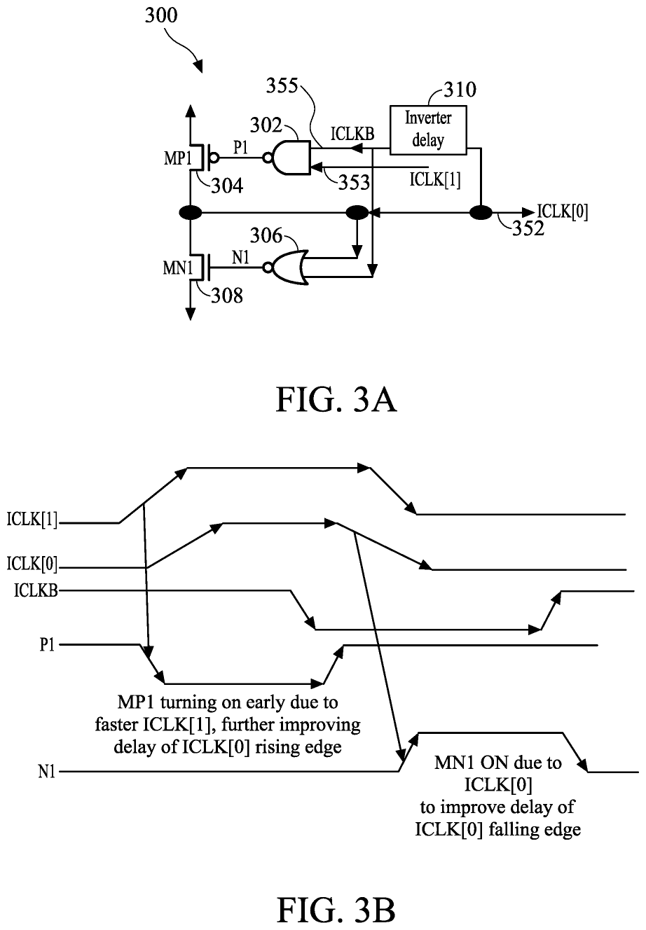

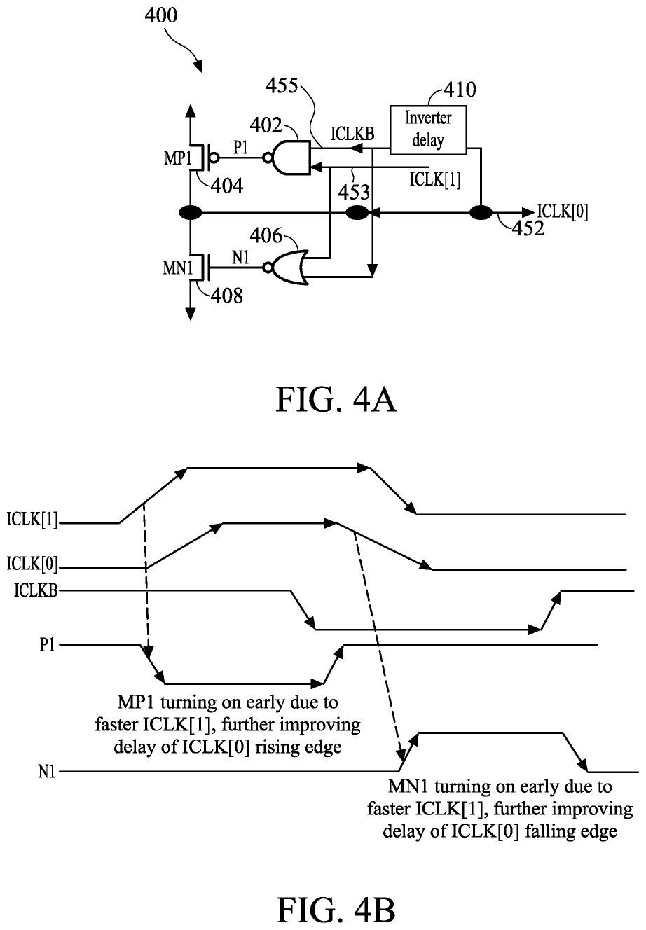

The clock generator 250 in FIG. 4 may be specifically configured to generate two separate clock signals. A first internal clock signal (ICLK[0]) 252 is generated and provided to both the first and second local clock drivers 212, 222 before it is input into a clock buffer 254 and then provided to the third and fourth local clock drivers 232, 242 as a modified signal (ICLK_BUF[0]) 256. Additionally, a second, faster internal clock signal (ICLK[1]) 253 is also created by the clock generator 250 and provided to only the first and the second local clock drivers 212, 222. Likewise, a similar third clock signal (ICLK_BUF[1]) 257, which is also faster than the modified internal clock signal (ICLK_BUF[0]) 256, may be created by the clock buffer 254 and provided to only the third and fourth local clock drivers 232, 242. As will be better understood with reference to FIGS. 3A-4B, the introduction of the faster clock signals (ICLK[1], ICLK_BUF[1]) 253, 257 allow the local clock drivers 212, 222, 232, 242 to improve the rising and falling edges of the internal clock signal (ICLK[0], ICLK_BUF[0]) 252, 256.

The second and third clock signals (ICLK[1], ICLK_BUF[1]) 253, 257 may have a reduced clock slew as compared to that of the first clock signal (ICLK[0]). In other words, the rate at which ICLK[1] rises from minimum to maximum may be increased with respect to that of ICLK[0]. This increased sharpness of the rising edge may reduce the amount of time it takes for the signal to reach its peak. Accordingly, the second and third clock signals (ICLK[1], ICLK_BUF[1]) 253, 257 may considered to be faster than the first clock signal (ICLK[0]) 252. The loading of the second, faster clock signal (ICLK[1]) 253 may be smaller than the loading of the first clock signal (ICLK[0]) 252. Additionally, the first clock signal (ICLK[0]) 252 and the second clock signal (ICLK[1]) 253 may be simultaneously provided to, for example, the first local clock driver 212.

FIG. 3A is a diagram of an example architecture for a local clock driver 300, which may be incorporated into the circuit of FIG. 2. The local clock driver 300 includes a NAND gate 302 electrically connected to a first transistor (MP1) 304, as well as a NOR gate 306 electrically connected to a second transistor (MN1) 308. Additionally, an inverter delay circuit 310 may be configured to first receive the internal clock signal (ICLK[0]) 352 and to produce a delayed, inverted clock signal (ICLKB) 355 that is then provided to both the NAND gate 302 and the NOR gate 306. The NAND gate 302 may be configured to receive the second, faster clock signal (ICLK[1]) 353. In this embodiment, the second clock signal (ICLK[1]) 353 is only provided to the NAND gate 302, while the NOR gate 306 may be configured to receive the internal clock signal (ICLK) 352. The impact of the additional clock signal (ICLK[1]) 353 on the functionality of the local clock driver 300 will be better understood with reference to FIG. 3B.

FIG. 3B depicts a related timing diagram showing an example operation of the local clock driver architecture of FIG. 3A. In comparison to a system that relies on only a single clock signal (ICLK), the addition of the faster ICLK[1] signal causes MP1 to turn on earlier than if the NAND gate 302 were to only receive the first clock signal (ICLK[0]), which improves the rising edge of the internal clock signal (ICLK[0]). In other words, the delay between turning on MP1 and the rising edge of the internal clock signal (ICLK[0]) has been reduced and, as a result, the delay of the rising edge of the ICLK[0] signal has been improved (i.e., the slope of the rising edge of ICLK[0] is more gradual) and the inverter delay between ICLK[0] and ICLKB has been reduced.

FIG. 4A is a diagram of an example architecture for a local clock driver 400, which may be incorporated into the circuit of FIG. 2. Similar to the local clock driver 300 of FIG. 3A, the local clock driver 400 includes a NAND gate 402 electrically connected to a first transistor (MP1) 404, as well as a NOR gate 406 electrically connected to a second transistor (MN1) 408. Additionally, an inverter delay circuit 410 may be configured to first receive the internal clock signal (ICLK[0]) 452 and to produce a delayed, inverted clock signal (ICLKB) 453 that is then provided to both the NAND gate 402 and the NOR gate 406. However, unlike in the local clock driver 300 of FIG. 3A, in this embodiment, both the NAND gate 402 and the NOR gate 406 are configured to receive a second, faster clock signal (ICLK[1]) 453. The impact of the additional clock signal (ICLK[1]) 453 being provided to both the NAND gate 402 and the NOR gate 406 on the functionality of the local clock driver 400 will be better understood with reference to FIG. 4B.

FIG. 4B depicts a related timing diagram showing an example operation of the local clock driver architecture of FIG. 4A. In comparison to the timing diagram of FIG. 3B, the example architecture of FIG. 4A keeps the advantages related to the rising edge of the ICLK[0] signal, and the receipt of the second, faster ICLK[1] signal by the NOR gate also causes MN1 to turn on earlier than if the NOR gate 402 were to only receive the first clock signal (ICLK[0]), which improves the falling edge of the internal clock signal (ICLK[0]). In other words, the delay between turning on MN1 and the falling edge of the internal clock signal (ICLK[0]) has been reduced and, as a result, the delay of the falling edge of the ICLK[0] signal has been improved (i.e., the slope of the rising edge of ICLK[0] is more gradual) and the inverter delay between ICLK[0] and ICLKB following the falling edge has been reduced. The embodiment of FIGS. 4A-4B may produce an improvement in clock to Q time by at least 3% or more compared to a single clock signal architecture.

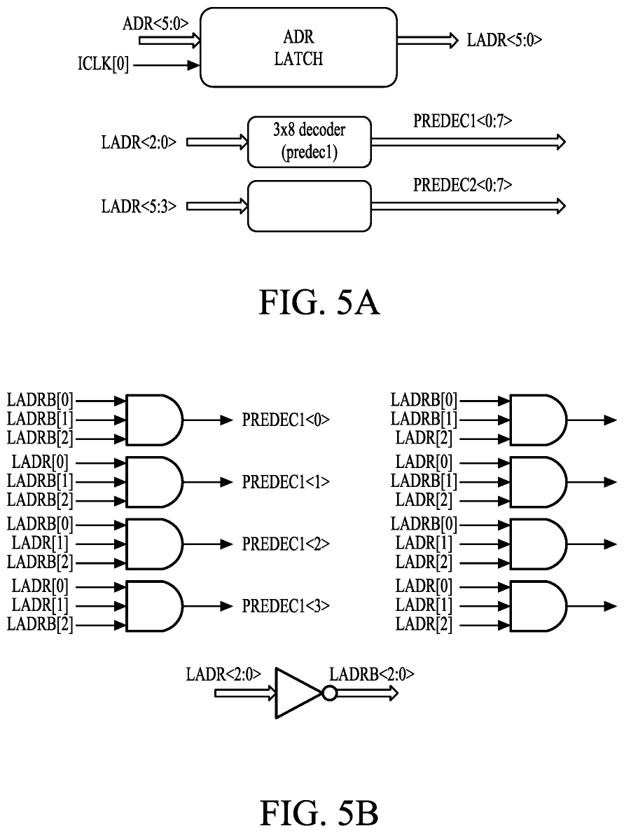

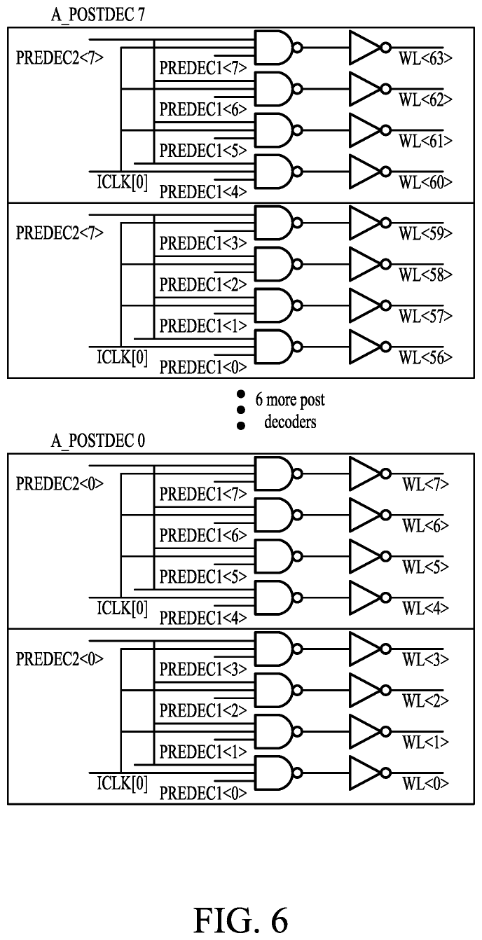

FIG. 5A is a diagram of example circuitry for an address latch and pre-decoder that may be incorporated into the circuit of FIG. 2. As shown, the ADR latch may receive the internal clock signal (ICLK[0]) and provide it to the ADR latch along with a global address signal (ADR<5:0>). The ADR latch may then produce a resulting signal (LADR<5:0>) which may be provided to two separate 3×8 decoders. FIG. 5B is a diagram of an example circuit for such a 3×8 pre-decoder using resulting signal (LADR<2:0). As shown, various address bits may be provided each of the eight decoders which may then output device selection signals, collectively (LADRB<2:0>), that may be used to select memory cells within each memory bank. The memory system may utilize six address bits and 64 word lines. FIG. 6 is a diagram of an example word line post-decoder that may be incorporated into the circuit of FIG. 2. The word line post-decoder may receive the device selection signals (e.g., PREDEC1<7:0>) provided from the pre-decoder in order to generate the various word lines (e.g., WL<7:0>) that may be used to perform operations within each memory bank.

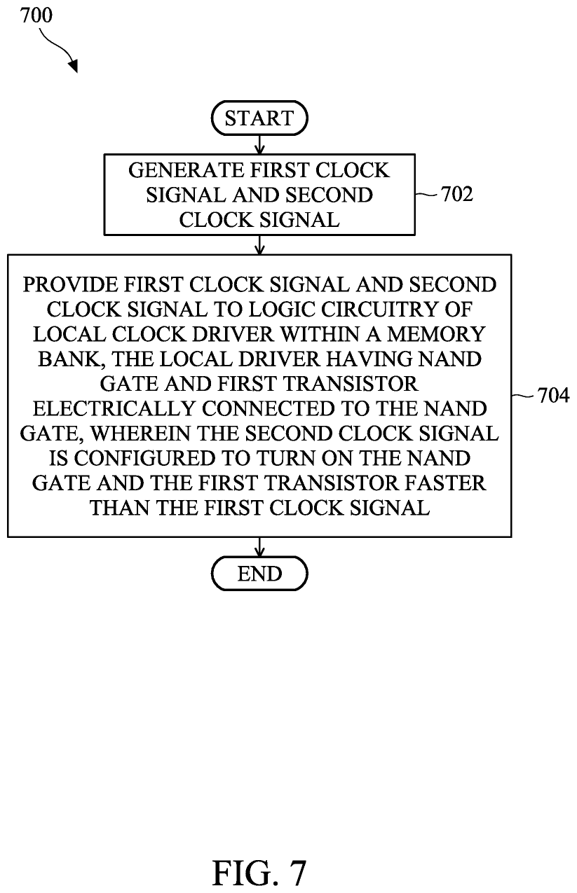

FIG. 7 is a flow diagram of an example method 700 for providing clock signals to a memory bank of a memory circuit, in accordance with an embodiment. The method 700 may, for example, be performed by the example memory circuit 200 shown in FIG. 2. At 702, a first clock signal and a second clock signal may be generated. At 704, the first clock signal and the second clock signal may be provided to logic circuitry of a local clock driver within a memory bank. The local driver may specifically have a NAND gate and a first transistor electrically connected to the NAND gate. Additionally, the second clock signal may be configured to turn on the NAND gate and the first transistor faster than the first clock signal.

In one example, a local clock driver in a memory circuit is provided. The local clock driver may include a NAND gate, a NOR gate, a first transistor electrically connected to the NAND gate, and a second transistor electrically connected to the NOR gate. The NAND gate and the NOR gate may be configured to receive a first clock signal, and the NAND gate may be further configured to receive a second clock signal that is faster than the first clock signal.

In another example, a memory circuit is provided. The memory circuit may include a clock generator configured to generate a first clock signal and a second clock signal, wherein the second clock signal is faster than the first clock signal and a first memory bank. The first memory bank may include a plurality of memory cells and a first local clock driver in electrical communication with the plurality of memory cells of the first memory bank; the first local clock driver configured to receive both the first clock signal and the second clock signal.

In yet another example, a method for providing clock signals to a memory bank of a memory circuit is provided. The method may include generating a first clock signal and a second clock signal and providing the first clock signal and the second clock signal to logic circuitry of a local clock driver within a memory bank, the local driver having a NAND gate and a first transistor electrically connected to the NAND gate, wherein the second clock signal is configured to turn on the NAND gate and the first transistor faster than the first clock signal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory circuit comprising:
a clock generator configured to generate a first clock signal and a second clock signal, wherein the second clock signal is faster than the first clock signal; and
a first memory bank including:
a plurality of memory cells; and
a first local clock driver in electrical communication with the plurality of memory cells of the first memory bank; the first local clock driver configured to receive both the first clock signal and the second clock signal.

2. The memory circuit of claim 1, further comprising:
a second memory bank including:
a plurality of memory cells; and
a second local clock driver in electrical communication with the plurality of memory cells of the second bank, the second local clock driver configured to receive the first clock signal.

3. The memory circuit of claim 1, wherein the second local clock driver is configured to also receive the second clock signal.

4. The memory circuit of claim 1, further comprising:
a third memory bank including:
a plurality of memory cells; and
a third local clock driver in electrical communication with the plurality of memory cells of the third bank, the third local clock driver configured to receive the first clock signal; and
a fourth memory bank including:
a plurality of memory cells; and
a fourth local clock driver in electrical communication with the plurality of memory cells of the fourth bank, the fourth local clock driver configured to receive the first clock signal.

5. The memory circuit of claim 4, wherein the third memory bank and the fourth memory bank are not configured to receive the second clock signal.

6. The memory circuit of claim 4, further comprising:
a clock buffer configured to receive the first clock signal and to generate a third clock signal from the first clock signal.

7. The memory circuit of claim 6, wherein the third clock signal is faster than the first clock signal.

8. The memory circuit of claim 7, wherein the third local clock driver and the fourth local clock driver are both configured to receive the third clock signal.

9. The memory circuit of claim 1, wherein the first clock signal and the second clock signal are simultaneously provided to the first local clock driver.

10. A local clock driver in a memory circuit, the local clock driver comprising:
a NAND gate;
a NOR gate;
a first transistor electrically connected to the NAND gate; and
a second transistor electrically connected to the NOR gate, wherein the NAND gate and the NOR gate are configured to receive a first clock signal, and the NAND gate is further configured to receive a second clock signal that is faster than the first clock signal.

11. The local clock driver of claim 10, wherein the receipt of the second clock signal by the NAND gate causes the first transistor to turn on earlier than if the first transistor was instead configured to only receive the first clock signal.

12. The local clock driver of claim 11, wherein the receipt of the second clock signal by the NAND gate improves a delay in the rising edge of the first clock signal.

13. The local clock driver of claim 10, wherein the NOR gate is further configured to receive the second clock signal.

14. The local clock driver of claim 13, wherein the receipt of the second clock signal causes the second transistor to turn on earlier than if the second transistor was instead configured to only receive the first clock signal.

15. The local clock driver of claim 14, wherein the receipt of the second clock signal by the NOR gate improves a delay in the falling edge of the first clock signal.

16. The local clock driver of claim 10, further comprising an inverter delay circuit, wherein the NAND gate and the NOR gate are configured to receive the first clock signal through the inverter delay circuit.

17. The local clock driver of claim 10, wherein the loading of the second clock signal is smaller than the loading of the first clock signal.

18. A method for providing clock signals to a memory bank of a memory circuit, the method comprising:
generating a first clock signal and a second clock signal;
providing the first clock signal and the second clock signal to logic circuitry of a local clock driver within a memory bank, the local driver having a NAND gate and a first transistor electrically connected to the NAND gate, wherein the second clock signal is configured to turn on the NAND gate and the first transistor faster than the first clock signal.

19. The method of claim 18, wherein the receipt of the second clock signal by the NAND gate causes the first transistor to turn on earlier than if the first transistor was instead configured to only receive the first clock signal.

20. The method of claim 18, wherein the receipt of the second clock signal by the NAND gate improves a delay in the rising edge of the first clock signal
